(19) United States
(12) Patent Application Publication
(10) Pub. No.: US 2026/0050014 A1
(43) Pub. Date: Feb. 19, 2026

(54) CURRENT SENSING DEVICE AND ELECTRONIC DEVICE

(71) Applicant: Pu-Dan Limited Corp., New Taipei City (TW)

(72) Inventor: Wei-Chih HUANG, New Taipei City (TW)

(21) Appl. No.: 19/298,268

(22) Filed: Aug. 13, 2025

(30) Foreign Application Priority Data
Aug. 16, 2024 (TW) 113130919
May 23, 2025 (TW) 114119447

(51) Int. Cl. G01R 19/00; G01R 19/25; G01R 35/00

(52) U.S. Cl. CPC G01R 19/0023; G01R 19/25; G01R 35/005

(57) ABSTRACT

A current sensing device including a lead frame and a sensor die is provided. The lead frame includes a first pad, a second pad, a third pad, and a connection line. The first pad is coupled to a first power source and receives a specific current provided by the first power source. The second pad is coupled to a load. The third pad provides a data signal to a microcontroller. The connection line is electrically coupled to the first and second pads. The sensor die obtains current information which is a current passing through the connection line according to a voltage difference between the first and second pads and an equivalent impedance of the connection line. The sensor die provides the data signal according to the current information. The lead frame is packaged together with the sensor die.

### CROSS REFERENCE TO RELATED APPLICATIONS

This application claims the benefit of and priority to Taiwan Patent Application No. 113130919, filed on Aug. 16, 2024, and Taiwan Patent Application No. 114119447, filed on May 23, 2025, the entireties of both of which being incorporated by reference herein.

### TECHNICAL FIELD

The present disclosure relates to a current sensing device, and, in particular, to a current sensing device combining a lead frame and a sensor die.

### BACKGROUND

In daily life, electronic devices use power to drive electronic circuits. In the interests of reducing power consumption, it is important to accurately monitor the voltage and current of this power. Therefore, monitoring current is an important trend.

### BRIEF SUMMARY

An embodiment of the present disclosure provides a current sensing device. The current sensing device comprises a lead frame and a sensor die. The lead frame comprises a first pad, a second pad, a third pad, and a connection line. The first pad is coupled to a first power source and receives a specific current provided by the first power source. The second pad is coupled to a load. The third pad provides a data signal to a microcontroller. The connection line is electrically coupled to the first and second pads. The sensor die obtains current information which is the current passing through the connection line according to a voltage difference between the first and second pads and an equivalent impedance of the connection line. The sensor die provides the data signal according to the current information. The lead frame is packaged together with the sensor die.

An embodiment of the present disclosure provides an electronic device comprising a printed circuit board (PCB) and a current sensing device. The PCB comprises a first element and a second element. The current sensing device is soldered on the PCB to measure the current between the first and second elements and comprises a lead frame and a sensor die. The lead frame comprises a first pad, a second pad, a third pad, and a connection line. The first pad is coupled to the first element. The second pad is coupled to the second element. The third pad provides a data signal to a microprocessor. The connection line is electrically coupled to the first and second pads. The sensor die obtains current information which is the current passing through the connection line according to a voltage difference between the first and second pads and an equivalent impedance of the connection line. The sensor die provides the data signal according to the current information. The lead frame is packaged together with the sensor die.

### BRIEF DESCRIPTION OF THE DRAWINGS

The present disclosure can be more fully understood by reading the subsequent detailed description and examples with references made to the accompanying drawings, wherein:

FIG. 1 is a schematic diagram of an exemplary embodiment of a current sensing device according to various aspects of the present disclosure;

FIG. 2A is a schematic diagram of the packaging of the current sensing device according to various aspects of the present disclosure;

FIG. 2B is a schematic diagram of the appearance of the current sensing device according to various aspects of the present disclosure;

FIG. 3A is another schematic diagram of the packaging of the current sensing device according to various aspects of the present disclosure;

FIG. 3B is another schematic diagram of the appearance of the current sensing device according to various aspects of the present disclosure;

FIGS. 4A˜4C are schematic diagrams of other exemplary embodiments of the current sensing device according to various aspects of the present disclosure;

FIG. 5A is another schematic diagram of the packaging of the current sensing device according to various aspects of the present disclosure;

FIG. 5B is another schematic diagram of the appearance of the current sensing device according to various aspects of the present disclosure;

FIG. 6A is a schematic diagram of an exemplary embodiment of a sensor die according to various aspects of the present disclosure; and

FIG. 6B is a schematic diagram of another exemplary embodiment of the sensor die according to various aspects of the present disclosure.

### DETAILED DESCRIPTION

The present disclosure will be described with respect to particular embodiments and with reference to certain drawings, but the disclosure is not limited thereto and is only limited by the claims. The drawings described are only schematic and are non-limiting. In the drawings, the size of some of the elements may be exaggerated for illustrative purposes and not drawn to scale. The dimensions and the relative dimensions do not correspond to actual dimensions in the practice of the present disclosure.

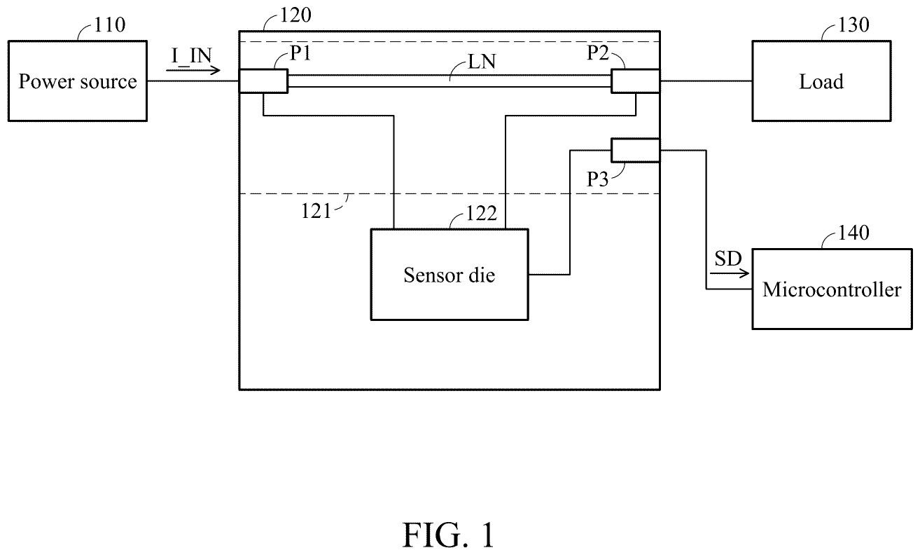

FIG. 1 is a schematic diagram of an exemplary embodiment of a current sensing device according to various aspects of the present disclosure. The current sensing device 120 comprises a lead frame 121 and a sensor die 122. The manufacturing process of the lead frame 121 is not limited in the present disclosure. In one embodiment, the lead frame 121 is formed by a stamping process or by an etching process. In another embodiment, under the requirement of high precision, the lead frame 121 is formed by a laser cutting process. In this case, the pads P1˜P3 are not have burrs. In some embodiments, the material of the lead frame 121 is a nickel-copper alloy.

The pad P1 is coupled to a power source 110 and receives a specific current I_IN provided by the power source. In one embodiment, the specific current I_IN may be between 3A˜30A. The pad P2 is coupled a load 130 and outputs the specific current I_IN to the load 130. The pad P3 provides a data signal SD to a microcontroller 140. The connection line LN is electrically coupled to the pads P1 and P2. In one embodiment, the equivalent impedance of the connection line LN is within 1 mΩ˜20 mΩ. The width of the connection line LN is not limited in the present disclosure. In this embodiment, the width of the connection line LN is smaller than the width of the pad P1, but it is not limited thereto. In one embodiment, the width of the connection line LN is the same as the width of the pad P1.

In some embodiments, the size of the pad P1 is the same as the size of the pad P2 and larger than the size of the pad P3. In this case, since a large current flows through the pads P1 and P2, the pads P1 and P2 have a larger size to withstand the large current.

The sensor die 122 obtains the current information which is the current passing through the connection line LN according to a voltage difference between the pads P1 and P2 and an equivalent impedance of the connection line LN. In one embodiment, the sensor die 122 obtains the voltage difference between the pads P1 and P2. The sensor die 122 obtains the current information which is the current passing through the connection line LN according to the equivalent impedance of the connection line LN and the voltage difference between the pads P1 and P2. In this embodiment, the sensor die 122 provides the data signal SD according to the current information. The microcontroller 140 finds out the current passing through the connection line LN according to the data signal SD. In one possible embodiment, the data signal SD is an analog signal. In one embodiment, the sensor die 122 has an analog-to-digital function. In this case, the data signal SD is a digital signal. In some embodiments, the voltage of the pad P1 is used as the operating voltage of the sensor die 122. In other words, the power source 110 supplies power to the sensor die 122.

In this embodiment, the lead frame 121 and the sensor die 122 are packaged together to form a single component. In some embodiments, the technology for packaging the lead frame 121 and the sensor die 122 is a flip chip packaging technology or a wire bonding packaging technology. Since the lead frame 121 and the sensor die 122 are not two independent components, there is no need to use a soldering technology to solder the lead frame 121 and the sensor die 122 on the same printed circuit board (PCB). Therefore, the contact impedance caused by additional solder can be reduced and the current sensing accuracy of the sensor die 122 can be improved. The error value of the current sensing of the sensor die 122 may be caused by the contact impedance due to the additional soldering. Furthermore, since the lead frame 121 and the sensor die 122 are packaged together, the sensor die 122 is very close to the connection line LN. In the process of measuring the current passing through the connection line LN, the measurement result of the sensor die 122 is not easily affected by noise interference.

During the final test process of the production stage, the power source 110, the load 130 and the microcontroller 140 are utilized to sequentially or simultaneously correct many current sensing devices to obtain the error values of the current sensing devices. After the correction is completed, the current sensing devices can be used in servers, industrial computers, smart meters, and USB fast charging (power delivery) fields as current monitoring elements. Since the power source 110, the load 130 and the microcontroller 140 are used as test device, after the test is completed, the current sensing device 120 does not need to be coupled to the power source 110, the load 130 and the microcontroller 140. Users can apply the current sensing device 120 to any electronic device according to actual needs.

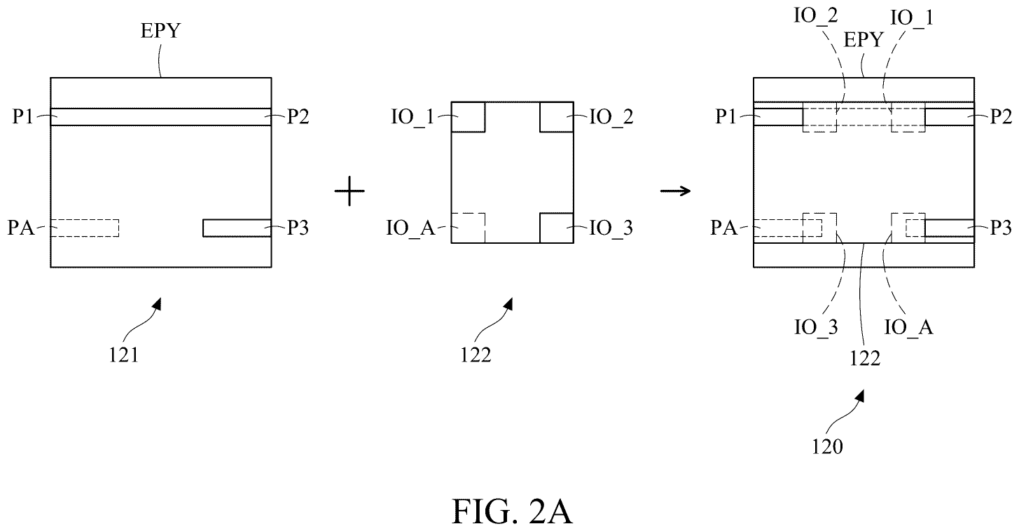

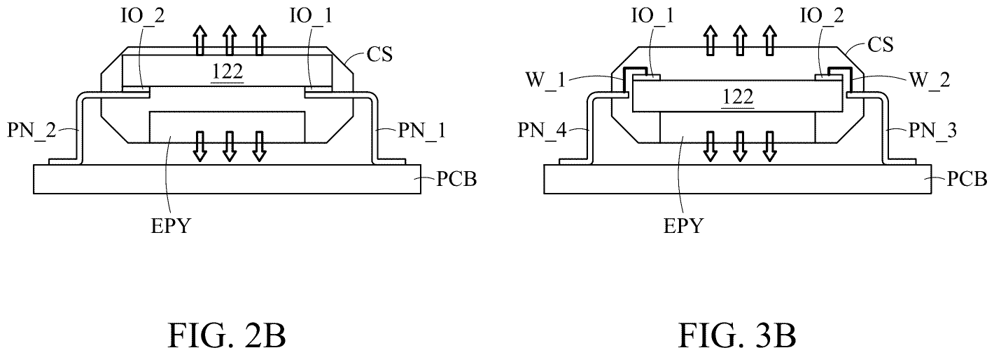

FIG. 2A is a schematic diagram of the packaging of the current sensing device 120 according to various aspects of the present disclosure. The lead frame 121 comprises the pads P1˜P3. In one embodiment, the lead frame 121 is disposed in a plastic material EPY. The plastic material EPY is used to support the lead frame 121 and fix the pads P1˜P3. The type of the plastic material EPY is not limited in the present disclosure. In one embodiment, the plastic material EPY is epoxy. In addition, the number of pads of the lead frame 121 is not limited in the present disclosure. In some embodiments, the lead frame 121 further comprises the pad PA.

FIG. 2A shows the front side of the sensor die 122. As shown in FIG. 2A, the sensor die 122 comprises pads IO_1˜IO_3. Generally, each wafer produced by a wafer manufacturing plant has many dies. After the wafer saw process, many independent dies can be obtained. In this embodiment, the sensor die 122 is a die saw from a wafer.

In FIG. 2A, the front side of the sensor die 122 is placed toward the lead frame 121 and contacts the lead frame 121. In this case, the pad IO_1 of the sensor die 122 contacts and electrically connects to the pad P2 of the lead frame 121, the pad IO_2 of the sensor die 122 contacts and electrically connects to the pad P1 of the lead frame 121, and the pad IO_3 of the sensor die 122 contacts and electrically connects to the pad PA of the lead frame 121. In other embodiments, the front surface of the sensor die 122 further comprises a pad IO_A for electrically connecting to the pad P3 of the lead frame 121.

Next, a packaging case is used to package the lead frame 121 and the sensor die 122 together. FIG. 2B is a schematic diagram of the appearance of the current sensing device 120 of FIG. 2A. The packaging case CS encapsulates the lead frame 121 and the sensor die 122. In some embodiments, the packaging case CS has a heat dissipation function to release the heat energy generated by the connection line LN when the current passing through.

In some embodiments, the current sensing device 120 further comprises a plurality of external pins for electrically connecting to the sensor die 122. For brevity, FIG. 2B only shows the external pins PN_1 and PN_2. The external pin PN_1 is electrically connected to the pad IO_1. The external pin PN_2 is electrically connected to the pad IO_2. The external pins PN_1 and PN_2 are exposed from the packaging case CS.

In this embodiment, the packaging technology for packaging the lead frame 121 and the sensor die 122 is a flip chip packaging technology. The packaged lead frame 121 and the packaged sensor die 122 serve as the current sensing device 120. The current sensing device 120 may be soldered on a printed circuit board PCB. In this case, the external pin PN_1 is coupled to the power source 110 through a trace (not shown) on the printed circuit board PCB, and the external pin PN_2 is coupled to the load 130 through another trace on the printed circuit board PCB.

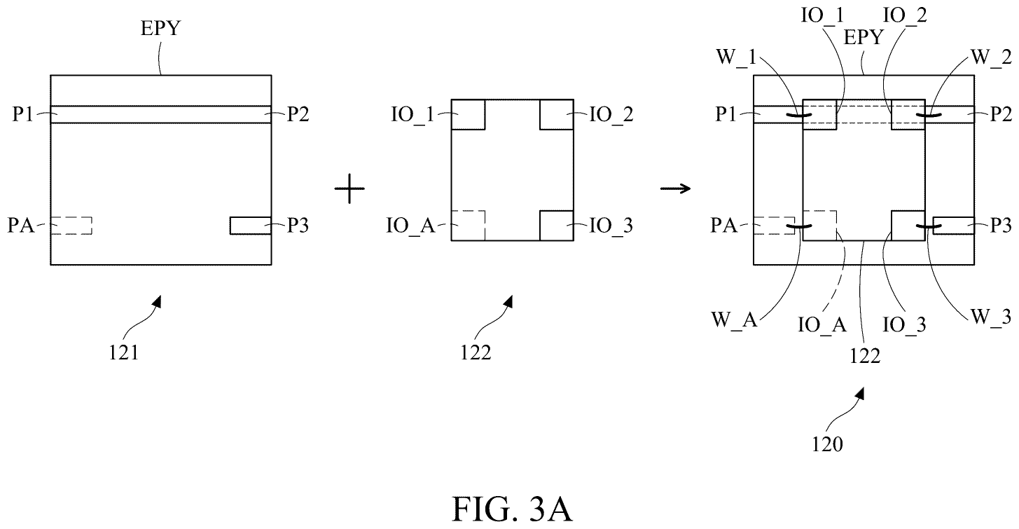

FIG. 3A is another schematic diagram of the packaging of the current sensing device according to various aspects of the present disclosure. In this embodiment, the packaging technology for packaging the lead frame 121 and the sensor die 122 is a wire bonding packaging technology. FIG. 3A shows the front side of the sensor die 122. First, the back side of the sensor die 122 faces the lead frame 121. Then, the pads on the front side of the sensor die 122 and the lead frame 121 are electrically connected by bonding wires W_1˜W_3 and W_A.

As shown in FIG. 3A, the bonding wire W_1 electrically connects the pad IO_1 of the sensor die 122 and the pad P1 of the lead frame 121. The bonding wire W_2 electrically connects the pad IO_2 of the sensor die 122 and the pad P2 of the lead frame 121. The bonding wire W_3 electrically connects the pad IO_3 of the sensor die 122 and the pad P3 of the lead frame 121. The bonding wire W_A electrically connects the pad IO_A of the sensor die 122 and the pad PA of the lead frame 121.

FIG. 3B is another schematic diagram of the appearance of the current sensing device according to various aspects of the present disclosure. FIG. 3B is similar to FIG. 2B, exception that the connection between the sensor die 122 and the lead frame 121 in the current sensing device of FIG. 3B uses bonding wires W_1˜W_3 and W_A. For brevity, FIG. 3B only shows the external pins PN_3 and PN_4. The external pin PN_3 is electrically connected to the pad IO_2 via the bonding wire W_2. The external pin PN_4 is electrically connected to the pad IO_1 via the bonding wire W_1.

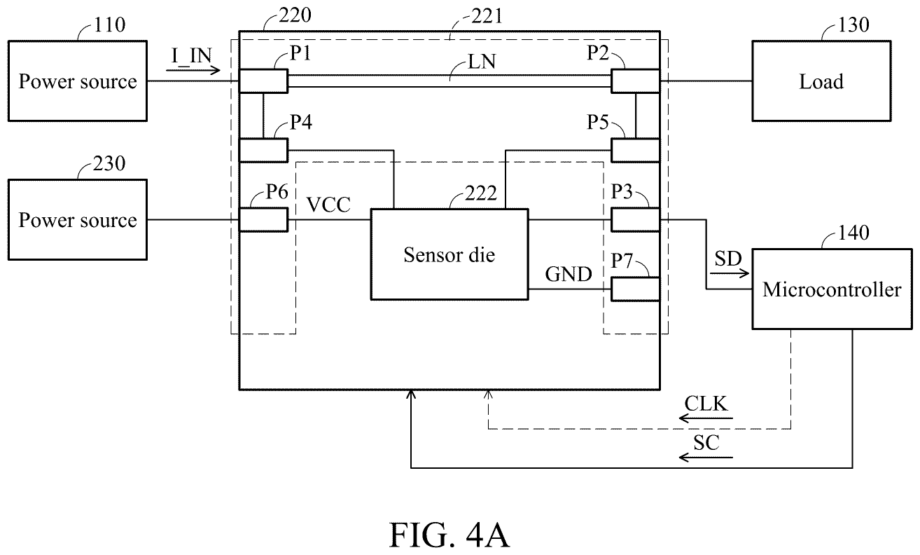

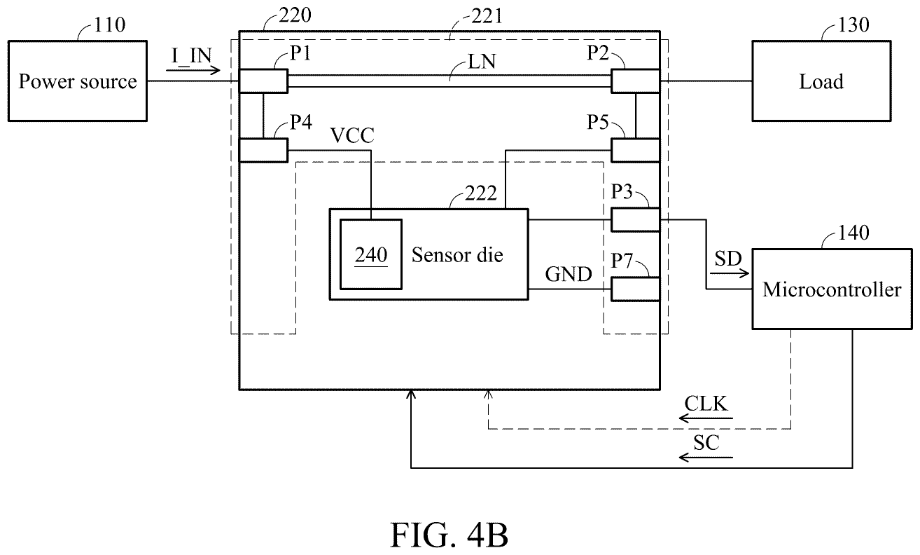

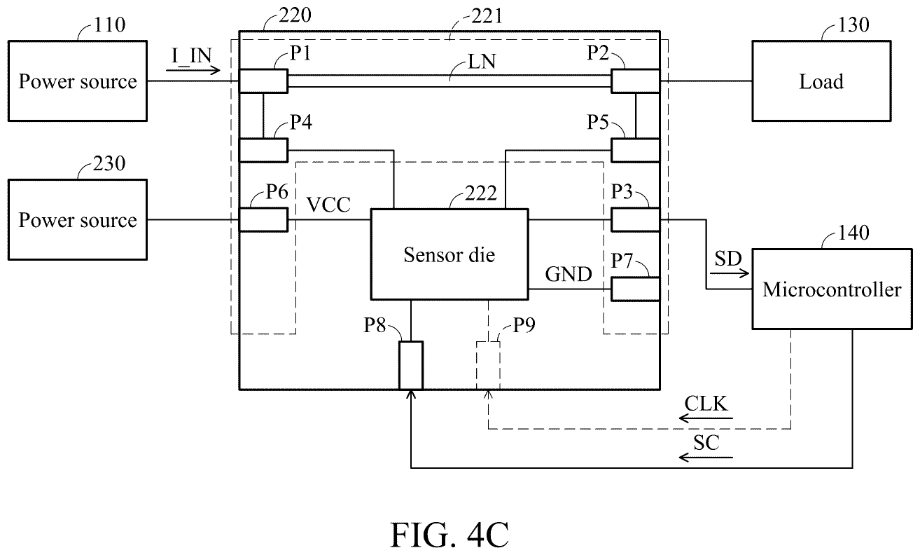

FIG. 4A is a schematic diagrams of an exemplary embodiments of the current sensing device according to various aspects of the present disclosure. The current sensing device 220 comprises a lead frame 221 and a sensor die 222. The lead frame 221 is similar to the lead frame 121 of FIG. 1, except that the lead frame 221 further comprises pads P4˜P7. The pad P4 is electrically connected to the pad P1 and the sensor die 222. The pad P5 is electrically connected to the pad P2 and the sensor die 222. In this case, the sensor die 222 senses the voltages of the pads P4 and P5 to obtain the voltage difference between the pads P1 and P2. The sensor die 222 obtains the current information which is the current passing through the connection line LN according to the voltage difference between the pads P1 and P2 and the equivalent impedance of the connection line LN. The sensor die 222 provides a data signal SD according to the current information. Since the characteristics of the sensor die 222 are similar to the characteristics of the sensor die 122, the related description is omitted here.

In one embodiment, the sensor die 222 directly uses the current passing through the connection line LN as the data signal SD. In another embodiment, the sensor die 222 converts the current passing through the connection line LN and uses the converted result as the data signal SD. In this case, the data signal SD may be an analog signal or a digital signal.

The pad P6 is coupled to a power source 230 to receive an operating voltage VCC provided by the power source 230. The pad P6 provides the operating voltage VCC to the sensor die 222. The pad P7 receives a ground voltage GND and provides the ground voltage GND to the sensor die 222. After receiving the operating voltage VCC and the ground voltage GND, the sensor die 222 starts to sense the voltages diffidence of the pads P1 and P2, and obtains the current information which is the current passing through the connection line LN.

FIG. 4B is a schematic diagrams of an exemplary embodiments of the current sensing device according to various aspects of the present disclosure. FIG. 4B is similar to FIG. 4A, exception that the sensor die 222 of FIG. 4B receives the operating voltage VCC provided by the power source 110 via the pad P4. In this case, the pad P6 can be omitted. In one embodiment, the sensor die 222 comprises a power circuit 240. The power circuit 240 converts the operating voltage VCC and then provides the converted voltage to other components inside the sensor die 222. In one embodiment, the power circuit 240 is a low dropout regulator (LDO).

FIG. 4C is a schematic diagrams of an exemplary embodiments of the current sensing device according to various aspects of the present disclosure. FIG. 4C is similar to FIG. 4A, exception that the lead frame 221 further comprises a pad P8. The pad P8 is couple to the microcontroller 140 and receives a control signal SC from the microcontroller 140. The sensor die 222 adjusts the data signal SD according to the control signal SC, and then provides the adjusted data signal SD to the microcontroller 140. The present disclosure does not limit how the sensor die 222 adjusts the data signal SD. In one embodiment, the sensor die 222 generates a calibration signal according to the control signal SC, and combines the calibration signal into the data signal SD.

The microcontroller 140 determines whether the adjusted data signal SD matches a predetermined value. When the data signal SD does not match the predetermined value, the microcontroller 140 sends the control signal SC again to request the sensor die 222 to re-adjust the data signal SD. In one embodiment, the sensor die 222 combines another calibration signal with the data signal SD until the data signal SD matches the predetermined value. When the data signal SD matches the predetermined value, the microcontroller 140 requests the sensor die 222 to record the adjustment level of the data signal SD and use the adjustment level as a reference value (referred to as an offset). In future current sensing results, the sensor die 222 adds the reference value to the measurement result as the final current measurement result.

For example, assume that the data signal SD output by the sensor die 222 indicates that the current passing through the connection line LN is 9.8 A. Since the current (9.8 A) passing through the connection line LN does not match a predetermined value (e.g., 10 A), the microcontroller 140 sends the control signal SC to request the sensor die 222 to adjust the data signal SD. In one embodiment, the sensor die 222 increases the data signal SD according to the control signal SC, so that the data signal SD corresponds to the current 9.9 A. Since the data signal SD corresponding to the current 9.9 A does not match the predetermined value (e.g., 10 A), the microcontroller 140 re-sends the control signal SC. The sensor die 222 continues to increase the data signal SD, so that the data signal SD corresponds to the current 10 A. Since the data signal SD corresponding to the current (10 A) matches the predetermined value (e.g., 10 A), the microcontroller 140 stops sending the control signal SC. The sensor die 222 records the increased level in the data signal SD (0.2 A).

After the current sensing device 220 is manufactured, the current sensing device 220 may be used in a server. Assume that the current which is measured by the sensing chip 222 and passes through the connection line LN is 5 A. In this case, the sensor die 222 adds the actual measurement result (e.g., 5A) to the previously recorded calibration value (e.g., 0.2 A), and then generates a data signal SD according to the calibrated current value (e.g., 5.2 A). The current sensing device 220 may provide the calibrated current value (e.g., 5.2 A) to an external test instrument or a microprocessor.

Since the data signal SD generated by the current sensing device 220 has been calibrated to compensate for the error caused by any factors in the package, it can provide accurate current monitoring results. Furthermore, since the connection line LN measured by the sensor die 222 is a part of the lead frame 221, no additional components are required, so the component cost will not be increased, and the current monitoring function can be provided.

In some embodiments, the lead frame 221 further comprises a pad P9. The pad P9 is coupled to the microcontroller 140 and receives a clock signal CLK from the microcontroller 140. In this case, the sensor die 222 receives the control signal SC according to the clock signal CLK. In one embodiment, the clock signal CLK and the control signal SC comply with an inter-integrated circuit (I2C) protocol.

The sizes of the pads P1˜P9 are not limited in the present disclosure. In one embodiment, the sizes of the pads P1˜P9 are the same. In another embodiment, the pads P1 and P2 have the same size, and the sizes of the pads P1 and P2 are larger than the sizes of the pads P3˜P9. In some embodiments, the pads P1, P2, P4 and P5 have the same size. In this case, the sizes of the pads P1, P2, P4 and P5 are larger than the sizes of the pads P3 and P6˜P9.

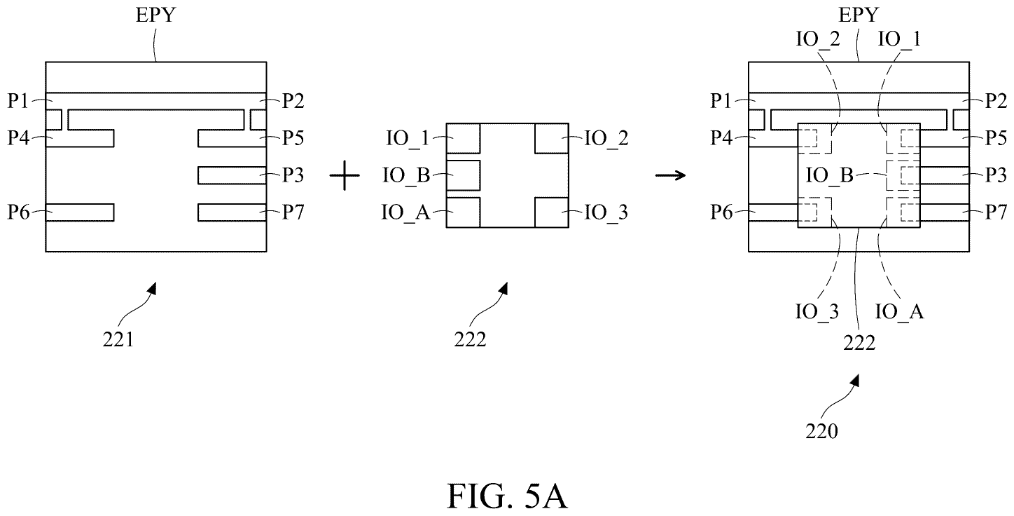

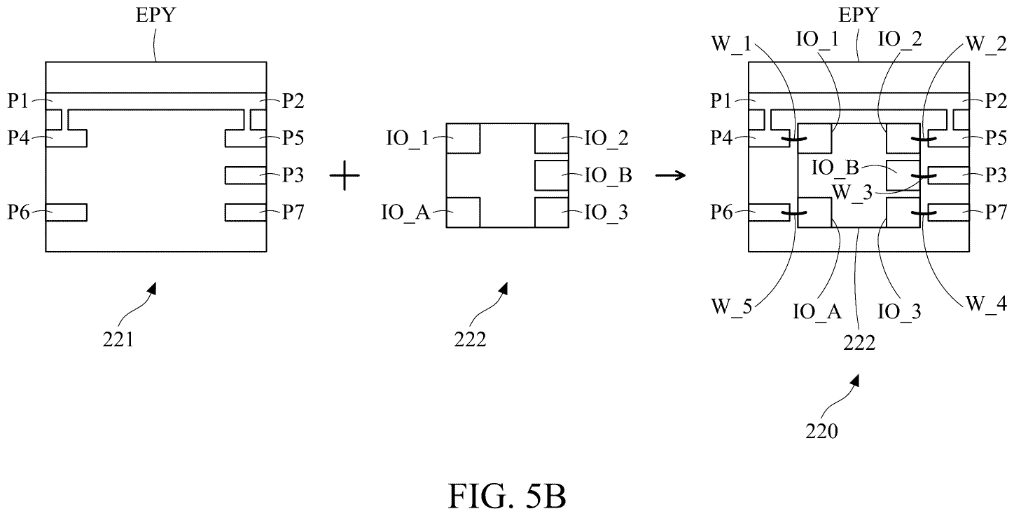

FIG. 5A is a schematic diagram of the packaging of the current sensing device 220 of FIG. 4A. The lead frame 221 comprises the pads P1˜P7. The pads P1˜P7 are fixed by the plastic material EPY. FIG. 5A shows the front side of the sensor die 222. As shown in FIG. 5A, the front side of the sensor die 222 comprises pads IO_1˜103, IO_A, and IO_B.

Next, the front side of the sensor die 222 is disposed toward the lead frame 221. In this case, the pad IO_1 of the sensor die 222 contacts and electrically connects to the pad P5 of the lead frame 221. In addition, the pad IO_2 of the sensor die 222 contacts and electrically connects to the pad P4 of the lead frame 221. The pad IO_3 of the sensor die 222 contacts and electrically connects to the pad P6 of the lead frame 221. The pad IO_A of the sensor die 222 contacts and electrically connects to the pad P7 of the lead frame 221. The pad IO_B of the sensor die 222 contacts and electrically connects to the pad P3 of the lead frame 221.

Finally, the lead frame 221 and the sensor die 222 are packaged together using a packaging case. In this embodiment, the packaging technology of the lead frame 221 and the sensor die 222 is a flip chip packaging technology. The packaged lead frame 221 and the packaged sensor die 222 serve as a current sensing device 220. The current sensing device 220 may be soldered on a printed circuit board to measure the current between two elements on the printed circuit board. Since FIG. 5A is similar to FIG. 2B, the related description is omitted here.

FIG. 5B is another schematic diagram of the appearance of the current sensing device 220 according to various aspects of the present disclosure. In this embodiment, the packaging technology for packaging the lead frame 221 and the sensor die 222 is a wire bonding packaging technology. The back side of the sensor die 222 faces the lead frame 221. Then, the sensor die 222 is electrically connected to the lead frame 221 via the bonding wires W_1˜W_5. As shown in FIG. 5B, the bonding wire W_1 electrically connects to the pad IO_1 of the sensor die 222 and the pad P4 of the lead frame 221. The bonding wire W_2 electrically connects to the pad IO_2 of the sensor die 222 and the pad P5 of the lead frame 221. The bonding wire W_3 electrically connects to the pad IO_B of the sensor die 222 and the pad P3 of the lead frame 221. The bonding wire W_4 electrically connects to the pad IO_3 of the sensor die 222 and the pad P7 of the lead frame 221. The bonding wire W_5 electrically connects to the pad IO_A of the sensor die 222 and the pad P6 of the lead frame 221. Finally, a packaging case is used to package the lead frame 221 and the sensor die 222. The current sensing device 220 may be soldered on a printed circuit board (not shown). Since FIG. 5B is similar to FIG. 3B, the related description is omitted here.

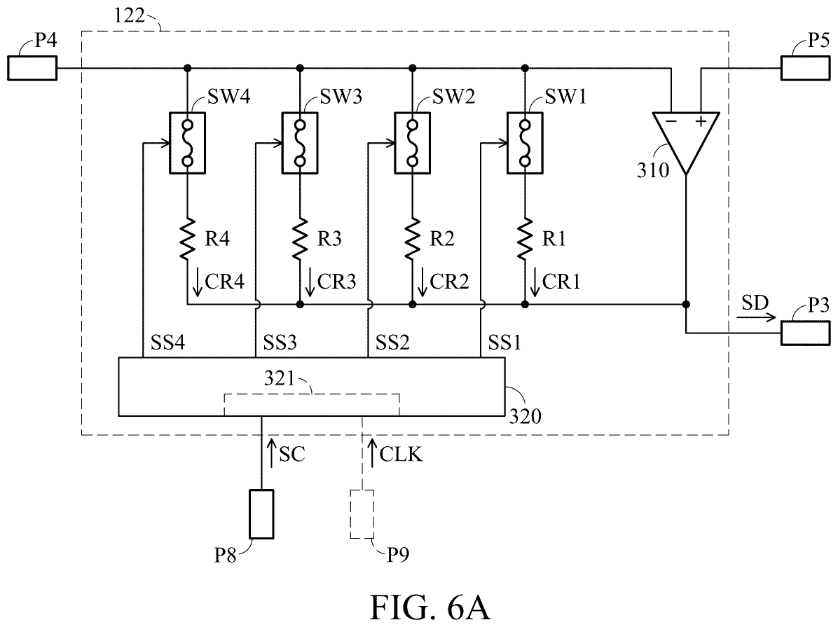

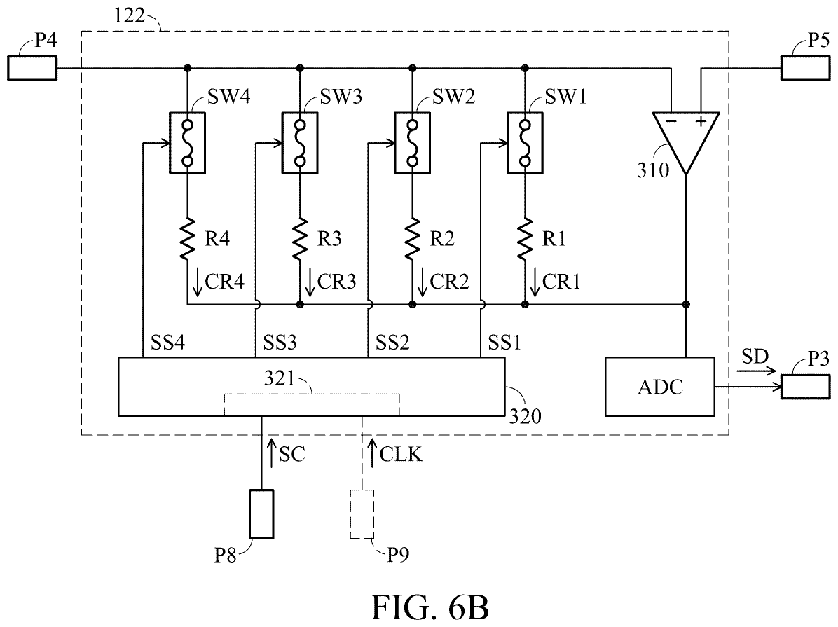

FIG. 6A is a schematic diagram of an exemplary embodiment of the sensor die 122 according to various aspects of the present disclosure. In this embodiment, the sensor die 122 comprises an operational amplifier 310, a processing circuit 320, switches SW1˜SW4, and resistors R1˜R4. The non-inverting terminal of the operational amplifier 310 is coupled to the pad P5. The inverting input terminal of the operational amplifier 310 is coupled to the pad P4. The output terminal of the operational amplifier 310 is coupled to the pad P3 to provide the data signal SD. In one embodiment, the operational amplifier 310 may output the voltage difference between the pads P4 and P5. In another embodiment, the operational amplifier 310 may output a current corresponding to the voltage difference between the pads P4 and P5.

The switch SW1 is connected to the resistor R1 in series between the pads P4 and P3, and receive a switching signal SS1. The switch SW2 is connected to the resistor R2 in series between the pads P4 and P3, and receive a switching signal SS2. The switch SW3 is connected to the resistor R3 in series between the pads P4 and P3, and receive a switching signal SS3. The switch SW4 is connected to the resistor R4 in series between the pads P4 and P3, and receive a switching signal SS4. The number of switches and resistors is not limited in the present disclosure. The number of switches is the same as the number of resistors. In other embodiments, the sensor die 222 comprises the more or the fewer switches and resistors.

The processing circuit 320 generates the switching signals SS1˜SS4 according to the control signal SC to turn on or off the corresponding switch. Taking the switch SW1 as an example, the switch SW1 may switch from a turned-on state to a turned-off state, or from a turned-off to a turned-on state, according to the switching signal SS1. The types of switches SW1˜SW4 are not limited in the present disclosure. In one embodiment, the switches SW1˜SW4 are electronic fuses (eFuses). Taking the switch SW1 as an example, the switch SW1 may switch from a short-circuit state to an open-circuit state, or from an open-circuit state to a short-circuit state, according to the switching signal SS1.

Assume that the specific current I_IN provided by the power source 110 is 10 A. When the microcontroller 140 obtains that the current passing through the connection line LN is 9.8 A according to the data signal SD, it means that the current sensing device 220 has an error of 0.2 A. Therefore, the microcontroller 140 uses the control signal SC to request the sensor die 222 to perform an error calibration. In this case, the sensor die 222 adjusts the data signal SD according to the control signal SC.

For example, the processing circuit 320 enables the switching signal SS1 and disables the switching signals SS2˜SS4 according to the control signal SC. Therefore, the switch SW1 is turned on, and the switches SW2˜SW4 are turned off. A negative feedback loop is formed by the switch SW1 and the resistor R1, and a calibration signal CR1 is added to the data signal SD. At this time, the microcontroller 140 obtains that the current of the connection line LN is 9.9 A according to the data signal SD. Since the current of the connection line LN does not match the specific current I_IN, the microcontroller 140 re-sends the control signal SC. The processing circuit 320 enables the switching signal SS2 and disables the switching signals SS1, SS3, and SS4 according to the control signal SC. Therefore, the switch SW2 is turned on, and the switches SW1, SW3, and SW4 are turned off. A negative feedback loop is formed by the switch SW2 and the resistor R2, and the sensor die 122 adds a calibration signal CR2 to the data signal SD. At this time, the microcontroller 140 obtains that the current of the connection line LN is 10 A according to the data signal SD. Since the current of the connection line LN matches a predetermined value (i.e., the specific current I_IN), the microcontroller 140 uses the control signal SC to require the sensor die 122 to fixedly add the calibration signal CR2 to the data signal SD. Therefore, the processing circuit 320 maintains the enabling of the switching signal SS2 and maintains the disabling of the switching signals SS1, SS3, and SS4.

In one embodiment, when the switches SW1-SW4 are electronic fuses, the processing circuit 320 may burn out the switches SW1, SW3 and SW4, so that the switches SW1, SW3 and SW4 are in an open-circuit state. In this case, only the switch SW2 is in a short-circuit state, so the calibration signal CR2 is combined to the data signal SD.

In other embodiments, the sensor die 122 further comprises a memory (not shown) for recording the calibration signal CR2. In this case, the sensor die 122 adjusts the data signal SD according to the calibration signal recorded in the memory. In some embodiments, the processing circuit 320 further comprises an I2C interface 321. The I2C interface 321 is coupled to the pads P8 and P9 to receive the control signal SC and the clock signal CLK.

FIG. 6B is a schematic diagram of another exemplary embodiment of the sensor die 122 according to various aspects of the present disclosure. FIG. 6B is similar to FIG. 6A except for the addition of an analog-to-digital converter (ADC) 330. The ADC 330 converts the combination of the output of the operational amplifier 310 and the calibration signal (at least one of CR1˜CR4) from an analog format into a digital format. The converted result generated by the ADC 330 is served as the data signal SD and provided to the pad P3. In this case, the converted result is a digital signal.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein. It will be understood that although the terms “first,” “second,” etc. may be used herein to describe various elements, these elements should not be limited by these terms. These terms are only used to distinguish one element from another.

While the disclosure has been described by way of example and in terms of the preferred embodiments, it should be understood that the disclosure is not limited to the disclosed embodiments. On the contrary, it is intended to cover various modifications and similar arrangements. Therefore, the scope of the appended claims should be accorded the broadest interpretation so as to encompass all such modifications and similar arrangements.

What is claimed is:

1. A current sensing device comprising:
a lead frame comprising:
a first pad coupled to a first power source and receiving a specific current provided by the first power source;
a second pad coupled to a load;
a third pad providing a data signal to a microcontroller; and
a connection line electrically coupled to the first and second pads;
a sensor die obtaining current information which is a current passing through the connection line according to a voltage difference between the first and second pads and an equivalent impedance of the connection line, and providing the data signal according to the current information,
wherein the lead frame is packaged together with the sensor die.

2. The current sensing device as claimed in claim 1, wherein the equivalent impedance of the connection line is within 1 mΩ˜20 mΩ.

3. The current sensing device as claimed in claim 1, wherein the lead frame further comprises:
a fourth pad coupled to a second power source, receiving an operating voltage provided by the second power source, and providing the operating voltage to the sensor die.

4. The current sensing device as claimed in claim 1, wherein the lead frame further comprises:
a fifth pad coupled to the microcontroller and receiving a control signal provided by the microcontroller,
wherein the sensor die generates a calibration signal according to the control signal and combines the calibration signal with the data signal.

5. The current sensing device as claimed in claim 4, wherein in response to the data signal matching a predetermined value, the microcontroller directs the sensor die to maintain the calibration signal.

6. The current sensing device as claimed in claim 5, wherein the sensor die comprises a plurality of electronic fuses, and the microcontroller utilizes the control signal to control the electronic fuses.

7. The current sensing device as claimed in claim 5, wherein the sensor die comprises:
a memory storing the calibration signal.

8. The current sensing device as claimed in claim 6, wherein a size of the first pad is larger than a size of the third pad.

9. The current sensing device as claimed in claim 4, wherein the lead frame further comprises:
a sixth pad coupled to the microcontroller and receiving a clock signal provided by the microcontroller,
wherein the sensor die receives the control signal according to the clock signal.

10. The current sensing device as claimed in claim 9, wherein the sensor die comprises:
an inter-integrated circuit (I2C) interface coupled to the fifth and the sixth pads.

11. The current sensing device as claimed in claim 9, wherein the sensor die further comprises:
an operational amplifier comprising:
an inverting input terminal electrically coupled to the first pad;
a non-inverting input terminal electrically coupled to the second pad; and
an output terminal electrically coupled to the third pad;
a first switch coupled to the first pad and receiving a first switching signal;
a first resistor coupled between the first switch and the third pad;
a second switch coupled to the first pad and receiving a second switching signal;
a second resistor coupled between the second switch and the third pad; and
a processing circuit generating the first and second switching signals according to the control signal.

12. The current sensing device as claimed in claim 11, wherein in response to the first switch being turned on, the second switch is turned off, and in response to the second switch being turned on, the first switch is turned off.

13. The current sensing device as claimed in claim 11, wherein the sensor die further comprises:
an analog-to-digital converter coupled to the output terminal of the operational amplifier, the first resistor, and the second resistor and providing a digital signal to the third pad.

14. The current sensing device as claimed in claim 1, wherein the sensor die further comprises:
a power circuit converting an operating voltage provided by the first power source to generate a converted voltage and providing the converted voltage to the sensor die,
wherein the first pad transmits the operating voltage provided by the first power source to the power circuit.

15. The current sensing device as claimed in claim 1, wherein the sensor die further comprises:
a power circuit converting an operating voltage provided by the first power source to generate a converted voltage and providing the converted voltage to the sensor die,
wherein the second pad transmits the operating voltage provided by the first power source to the load.

16. The current sensing device as claimed in claim 1, wherein the lead frame is formed by a laser cutting process, a stamping process or an etching process.

17. The current sensing device as claimed in claim 1, wherein the technology for packaging the lead frame and the sensor die is a flip chip packaging technology or a wire bonding packaging technology.

18. The current sensing device as claimed in claim 1, wherein the lead frame and the sensor die are encapsulated in a packaging case.

19. An electronic device, comprising:
a printed circuit board (PCB) comprising a first element and a second element; and
a current sensing device soldered on the PCB to measure a current between the first and second elements and comprising:
a lead frame comprising:
a first pad coupled to the first element;
a second pad coupled to the second element;
a third pad providing a data signal to a microprocessor; and
a connection line electrically coupled to the first and second pads;
a sensor die obtaining current information which is a current passing through the connection line according to a voltage difference between the first and second pads and an equivalent impedance of the connection line, and providing the data signal according to the current information,
wherein the lead frame is packaged together with the sensor die.

20. The electronic device as claimed in claim 19, wherein the sensor die comprises:
a memory storing a calibration signal; and
a processing circuit combining the calibration signal with the data signal.
